(19) United States
(12) Patent Application Publication
(10) Pub. No.: US 2026/0039293 A1
(43) Pub. Date: Feb. 5, 2026

(54) SWITCH CIRCUIT WITH BIDIRECTIONAL CURRENT SENSING

(71) Applicant: Richtek Technology Corporation, Zhubei City (TW)

(72) Inventors: Li-Di Lo, Hsinchu (TW); Chien-Fu Tang, Hsinchu (TW)

(21) Appl. No.: 19/244,261

(22) Filed: Jun. 20, 2025

Related U.S. Application Data
(60) Provisional application No. 63/676,904, filed on Jul. 30, 2024.

(30) Foreign Application Priority Data
Feb. 6, 2025 (TW) 114104432

(51) Int. Cl. H03K 17/687; G01R 19/00

(52) U.S. Cl. CPC H03K 17/687; G01R 19/0092

(57) ABSTRACT

A switch circuit with current sensing functionality includes: a first and second switch, coupled between a first and second terminal of the switch circuit, and configured to control a conductive state between the first and second terminal according to a control signal; and a current sensing circuit configured to sense a first switch current flowing through the first switch. The current sensing circuit includes: a third switch, a gate and a source of the third switch being coupled in parallel with the first switch to generate a third switch current; a first error amplifier circuit configured to control a drain voltage of the third switch to track a drain voltage of the first switch through feedback, thereby making the third switch current positively correlated to the first switch current; and a current-to-voltage conversion circuit configured to generate a sensing voltage based on the third switch current.

### CROSS REFERENCE

The present invention claims priority to the provisional application, Ser. No. 63/676,904, filed on Jul. 30, 2024 and claims priority to the TW patent application Ser. No. 114104432, filed on Feb. 6, 2025.

### BACKGROUND OF THE INVENTION

### Field of Invention

The present invention relates to a switch circuit. Particularly, it relates to a switch circuit with bidirectional current sensing functionality.

### Description of Related Art

FIG. 1 illustrates a current sensing circuit of the prior art. As shown in FIG. 1, a switch SW operates according to a control signal VG. When the control signal VG provides an appropriate driving voltage, the switch SW is turned on, thereby generating a current ISW flowing from a high-voltage terminal (VX) to a ground terminal through a sensing resistor RCS to generate a sensing voltage VCS that is proportional to the magnitude of the current ISW. The sensing voltage VCS is provided to a control circuit to acquire the magnitude of the system current for current controlling or protection.

However, the prior art mentioned above has disadvantages, including that the current flowing through the sensing resistor RCS causes conduction loss, which directly reduces system efficiency, particularly in high-power applications. In addition, under high-current conditions, the sensing resistor RCS may include a parallel configuration of three resistors, which not only increases the component area and cost, but also increases the complexity of the overall circuit design.

In view of the foregoing, and to overcome the drawbacks of the prior art, the present invention provides a switch circuit with current sensing functionality. Through the circuit design of the present invention, accurate current sensing can be achieved without requiring multiple resistors in parallel. Furthermore, the present invention is capable of sensing both positive and negative currents (i.e., current in one direction or in the opposite direction) flowing through the switch. Therefore, the present invention can reduce conduction loss caused by current sensing, reduce component area and cost, improve system efficiency, and allow sensing of either a positive current that is greater than or equal to 0, or a negative current that is less than or equal to 0.

### SUMMARY OF THE INVENTION

From one perspective, the present invention provides a switch circuit, comprising a first switch and a second switch, coupled between a first terminal and a second terminal of the switch circuit, and configured to control a conductive state between the first terminal and the second terminal according to a control signal; and a current sensing circuit, configured to sense a first switch current flowing through the first switch; wherein the current sensing circuit includes: a third switch, configured such that a gate and a source of the third switch are coupled in parallel with the first switch, to generate a third switch current; a first error amplifier circuit, configured to control a drain voltage of the third switch to track a drain voltage of the first switch through feedback control, such that the third switch current is positively correlated with the first switch current; and a current-to-voltage conversion circuit, configured to generate a sensing voltage based on the third switch current, wherein the sensing voltage is positively correlated with the first switch current.

In one embodiment, the current sensing circuit further includes a negative current sensing sub-circuit, configured to sense a first switch negative current flowing through the first switch; wherein the first switch current includes a first switch positive current and the first switch negative current, wherein the first switch positive current is greater than or equal to 0, and the first switch negative current is less than or equal to 0.

In one embodiment, the current-to-voltage conversion circuit includes a first current mirror circuit, coupled between an output terminal of the first error amplifier circuit and a sensing node, configured to generate a sensing current based on the third switch current; and a sensing resistor, coupled to the sensing node, configured to generate the sensing voltage based on the sensing current.

In one embodiment, the third switch current includes a third switch positive current and a third switch negative current, wherein the third switch positive current is greater than or equal to 0, and the third switch negative current is less than or equal to 0; wherein the negative current sensing sub-circuit includes a second error amplifier circuit, configured to control the drain voltage of the third switch to track the drain voltage of the first switch through feedback control, such that the third switch negative current is positively correlated with the first switch negative current; and a second current mirror circuit, coupled between an output terminal of the second error amplifier circuit and the sensing node, and configured to generate a negative sensing current based on the third switch negative current; wherein the sensing current includes a positive sensing current and the negative sensing current, wherein the positive sensing current is greater than or equal to 0, and the negative sensing current is less than or equal to 0.

In one embodiment, the first current mirror circuit includes a first transistor and a second transistor which are MOSFETs, wherein the first transistor and the second transistor operate in a saturation region.

In one embodiment, the negative current sensing sub-circuit includes a compensation resistor, coupled between the drain voltage of the first switch and the first error amplifier circuit; and a current source circuit, coupled to the compensation resistor to generate an offset voltage across the compensation resistor.

In one embodiment, a maximum absolute value of the first switch negative current is positively correlated with the offset voltage.

In one embodiment, the first switch and the third switch are MOSFETs and simultaneously operate in a linear region or a saturation region.

In one embodiment, the first error amplifier circuit includes an error amplifier, configured to generate an error amplified signal based on a voltage difference between the drain voltage of the first switch and the drain voltage of the third switch; and an output transistor, coupled between a drain of the third switch and the current-to-voltage conversion circuit, configured to control the drain voltage of the third switch to track the drain voltage of the first switch based on the error amplified signal.

In one embodiment, the second switch is configured as a depletion-mode Metal-Oxide-Semiconductor Field-Effect Transistor (MOSFET), and the first switch and the third switch are configured as enhancement-mode MOSFETS.

From another perspective, the present invention provides a switch circuit with bidirectional current sensing, comprising a first switch and a second switch, coupled between a first terminal and a second terminal of the switch circuit, and configured to control a conductive state between the first terminal and the second terminal according to a control signal; and a current sensing circuit, configured to sense a first switch current flowing through the first switch; wherein the current sensing circuit includes a sensing resistor; and a third switch, wherein a gate of the third switch is configured to be coupled to a gate of the first switch, and a source of the third switch is configured to be coupled, in series through the sensing resistor, to a source of the first switch, to generate a third switch current; wherein the sensing resistor generates a sensing voltage based on the third switch current, wherein the sensing voltage is proportional to the first switch current.

The objectives, technical details, features, and effects of the present invention will be better understood with regard to the detailed description of the embodiments below, with reference to the attached drawings.

### BRIEF DESCRIPTION OF THE DRAWINGS

FIG. 1 illustrates a prior art current sensing circuit.

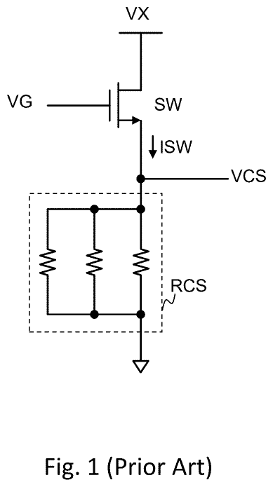

FIG. 2 illustrates a block diagram of an embodiment of a switch circuit with current sensing functionality according to the present invention.

FIGS. 3A and 3B illustrate block diagrams of two embodiments of the switch circuit with current sensing functionality according to the present invention.

FIG. 4 illustrates a schematic diagram of an embodiment of the switch circuit with current sensing functionality according to the present invention.

FIG. 5 illustrates a schematic diagram of an embodiment of the switch circuit with current sensing functionality according to the present invention.

FIG. 6 illustrates a schematic diagram of an embodiment of the switch circuit with current sensing functionality according to the present invention.

FIG. 7A illustrates a characteristic curve diagram of the sensing voltage and the first switch current corresponding to FIGS. 4 and 5 according to the present invention.

FIG. 7B illustrates a characteristic curve diagram of the sensing voltage and the first switch current corresponding to FIGS. 4 and 6 according to the present invention.

FIG. 8 illustrates a schematic diagram of an embodiment of the switch circuit with current sensing functionality according to the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

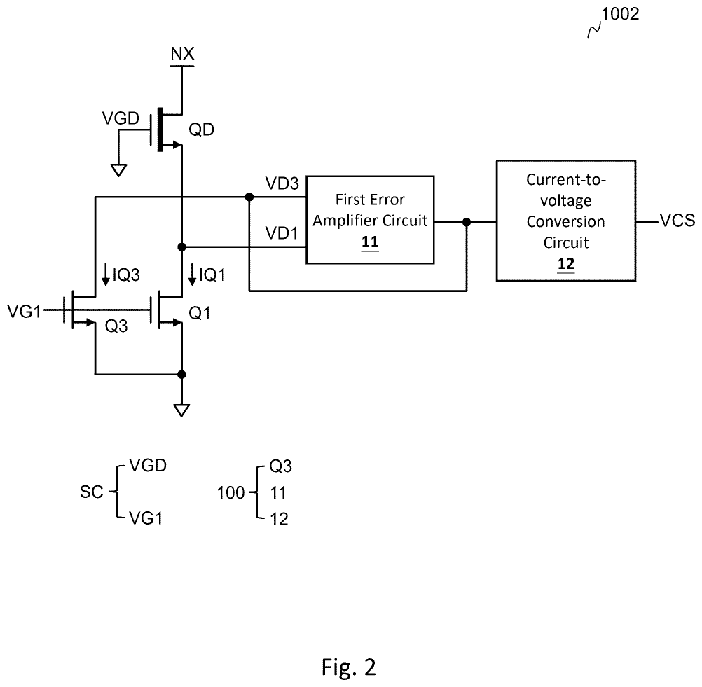

FIG. 2 illustrates a block diagram of an embodiment of a switch circuit with current sensing functionality according to the present invention. In one embodiment, a switch circuit 1002 comprises a first switch Q1, a second switch QD, and a current sensing circuit 100. The current sensing circuit 100 includes a third switch Q3, a first error amplifier circuit 11, and a current-to-voltage conversion circuit 12. In one embodiment, the first switch Q1 and the second switch QD are coupled between a first terminal and a second terminal of the switch circuit 1002 and configured to control a conductive state between the first and second terminals according to a control signal SC. In a specific embodiment, as shown in FIG. 2, the first and second terminals are coupled, respectively, to a ground potential and a switching node NX, for example. In one specific embodiment, the first switch Q1 and the second switch QD serve, for example, as low-side switches in a power stage circuit (such as a buck converter), and the switching node NX switches between a high voltage (e.g., 80V) and the ground potential. In one embodiment, the control signal SC includes a control signal VGD for controlling the second switch QD and a control signal VG1 for controlling the first switch Q1 and the third switch Q3.

In one embodiment, the current sensing circuit 100 is configured to sense a first switch current IQ1 flowing through the first switch Q1 to generate a sensing voltage VCS. In one embodiment, a gate and a source of the third switch Q3 are configured to be coupled in parallel with the first switch Q1. Specifically, the gate of the third switch Q3 is configured to be coupled to the gate of the first switch Q1, and the source of the third switch Q3 is configured to be coupled to the source of the first switch Q1, to generate a third switch current IQ3. In one embodiment, the first error amplifier circuit 11 is configured to control a drain voltage VD3 of the third switch Q3 to track a drain voltage VD1 of the first switch Q1 through feedback control, such that the third switch current IQ3 is positively correlated with the first switch current IQ1. For example, the feedback control of the first error amplifier circuit 11 is configured to control the drain voltage VD3 to either be equal to the drain voltage VD1 or differ from the drain voltage VD1 by an offset voltage, as will be described in detail below. The current-to-voltage conversion circuit 12 is configured to generate the sensing voltage VCS based on the third switch current IQ3. In one embodiment, the sensing voltage VCS is positively correlated with (e.g., proportional to) the first switch current IQ1.

In a specific embodiment, as shown in FIG. 2, the second switch QD is configured as a depletion-mode Metal-Oxide-Semiconductor Field-Effect Transistor (MOSFET), and the first switch Q1 and the third switch Q3 are configured as enhancement-mode MOSFETs. In this embodiment, the control signal VGD is a ground potential, which keeps the second switch QD conductive and indirectly clamps the drain voltage VD1 to approximately one threshold voltage (V_TH) below VGD.

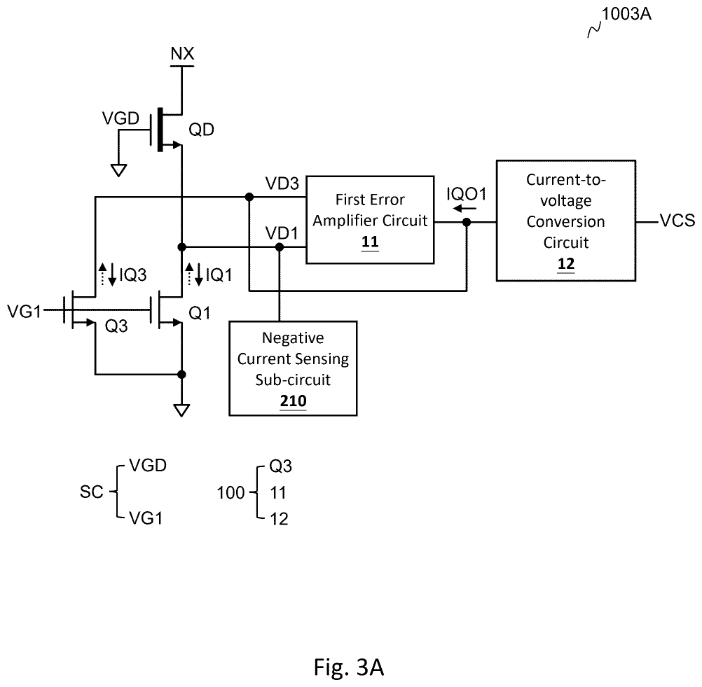

FIGS. 3A and 3B illustrate block diagrams of two embodiments of the switch circuit with current sensing functionality according to the present invention. The switch circuits 1003A and 1003B shown in FIGS. 3A and 3B are similar to the switch circuit 1002 in FIG. 2, and differ in that the current sensing circuits in 1003A and 1003B further include negative current sensing sub-circuits 210 and 220, respectively. In one embodiment, as shown in FIG. 3A, the negative current sensing sub-circuit 210 is coupled to the drain voltage VD1. In another embodiment, as shown in FIG. 3B, the negative current sensing sub-circuit 220 is coupled to the drain voltage VD1, the drain voltage VD3, and the sensing voltage VCS. The negative current sensing sub-circuits 210 and 220 are configured to sense a first switch negative current flowing through the first switch Q1.

In one embodiment, the first switch current IQ1 includes a first switch positive current and the first switch negative current, wherein the first switch positive current flows in one direction and the first switch negative current flows in the opposite direction. In one embodiment, the first switch positive current is greater than or equal to 0, and the first switch negative current is less than or equal to 0. As described above, since the third switch current IQ3 is positively correlated with the first switch current IQ1, the third switch current IQ3 also includes a third switch positive current and a third switch negative current, exhibiting the same characteristics as the first switch positive and negative currents. In one specific embodiment, as shown in FIGS. 3A and 3B, the first switch current IQ1 is illustrated as a solid-line arrow representing the first switch positive current or as a dashed-line arrow representing the first switch negative current, and the third switch current IQ3 is illustrated in the same manner to indicate the corresponding current direction.

It should be noted that, by employing the negative current sensing sub-circuits 210 and 220 shown in FIGS. 3A and 3B, the present invention can sense a first switch negative current flowing through the first switch Q1. Accordingly, the switch circuit of the present invention is capable of sensing either a positive current or a negative current flowing through the first switch Q1. It should further be noted that, at any given time, the first switch current IQ1 includes either the first switch positive current or the first switch negative current, but not both simultaneously. The same principle applies to the third switch current IQ3.

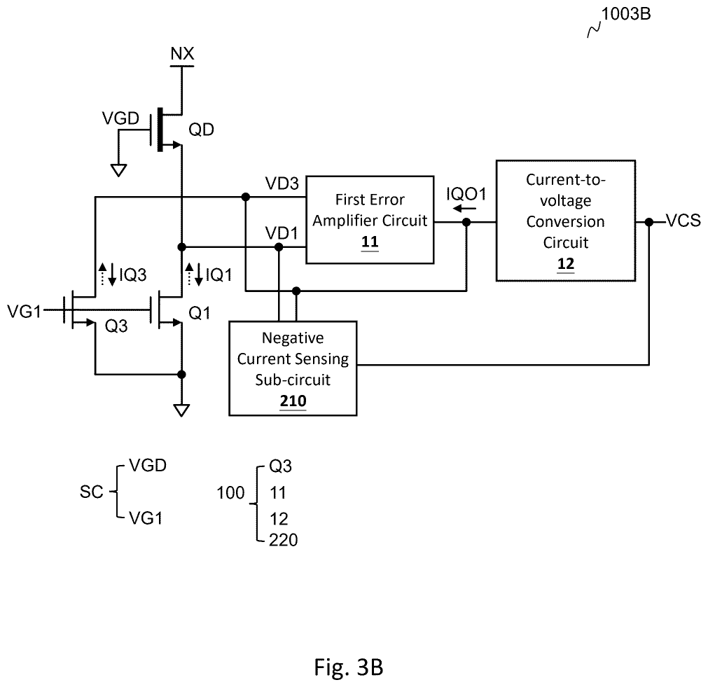

FIG. 4 illustrates a schematic diagram of an embodiment of the switch circuit with current sensing functionality according to the present invention. The switch circuit 1004 shown in FIG. 4 corresponds to a specific embodiment of the switch circuit 1002 in FIG. 2. In one embodiment, as shown in FIG. 4, the first error amplifier circuit 11 includes an error amplifier 14 and an output transistor QO1. In one embodiment, the error amplifier 14 is configured to generate an error amplified signal EA1 based on a voltage difference between the drain voltage VD1 of the first switch Q1 and the drain voltage VD3 of the third switch Q3. Specifically, a first input (non-inverting) terminal of the error amplifier 14 is connected to the drain voltage VD1 of the first switch Q1, and a second input (inverting) terminal is connected to the drain voltage VD3 of the third switch Q3. In one embodiment, the output transistor QO1 is configured as an NMOS transistor and is coupled between a drain of the third switch Q3 and the current-to-voltage conversion circuit 12, and is configured to generate an output current IQO1 based on the error amplified signal EA1. The error amplifier 14 is configured to control the drain voltage VD3 of the third switch Q3 to track the drain voltage VD1 of the first switch Q1 through negative feedback.

It should be understood that “the drain voltage VD3 of the third switch Q3 tracks the drain voltage VD1 of the first switch Q1” mentioned above refers to a condition in which the drain voltage VD3 substantially follows the behavior of the drain voltage VD1. For example, the drain voltage VD3 may be equal to the drain voltage VD1, or may differ from the drain voltage VD1 by a predetermined offset voltage. It should be noted that, since a gate-source voltage of the third switch Q3 is the same as that of the first switch Q1, and the drain voltage VD3 tracks the drain voltage VD1, the ratio of the third switch current IQ3 to the first switch current IQ1 is related to the ratio of the dimensions of the third switch Q3 to the first switch Q1. On the other hand, the first switch Q1 and the third switch Q3 operate simultaneously in either a linear region or a saturation region of MOSFET.

Referring still to FIG. 4, in one embodiment, the current-to-voltage conversion circuit 12 includes a first current mirror circuit 13 and a sensing resistor RCS. In one embodiment, the first current mirror circuit 13 includes MOSFET transistors Q4 and Q5, which operate in a saturation region. In this embodiment, the first current mirror circuit 13 is coupled between an output terminal of the first error amplifier circuit 11 and a sensing node NCS, and is configured to generate a sensing current ICS based on the third switch current IQ3. Specifically, as shown in FIG. 4, a transistor current IQ4 (equal to IQ3 and IQO1) flows through the transistor Q4 is configured to generated based on the output current IQO1. The first current mirror circuit 13 is supplied by the positive supply voltage VDD and configured to mirror the transistor current IQ4 to generate a transistor current IQ5 flowing through the transistor Q5, thereby generating the sensing current ICS flowing through the sensing resistor RCS. In one embodiment, the sensing resistor RCS is coupled between the sensing node NCS and the ground potential, and is configured to generate the sensing voltage VCS based on the sensing current ICS.

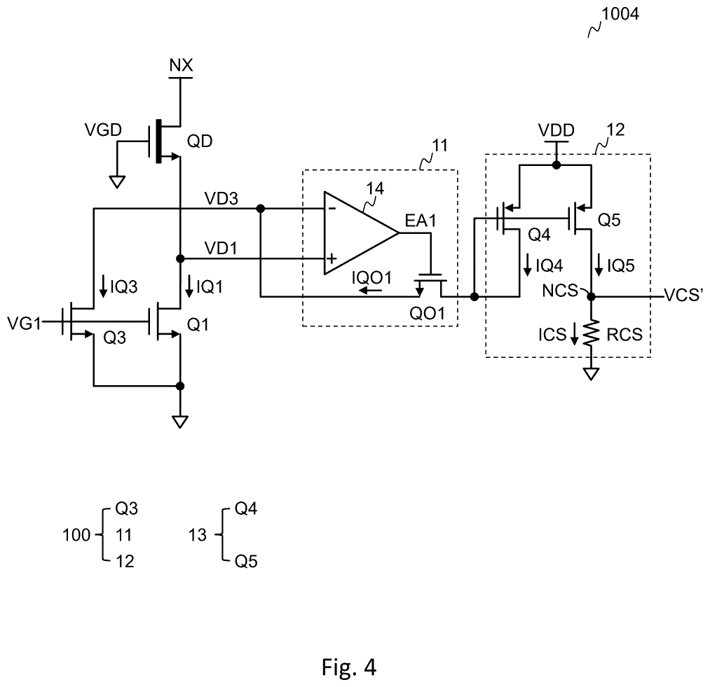

FIG. 5 illustrates a schematic diagram of an embodiment of the switch circuit with current sensing functionality according to the present invention. The switch circuit 1005 shown in FIG. 5 corresponds to a specific embodiment of the switch circuit 1003A in FIG. 3A. In one embodiment, as shown in FIG. 5, the negative current sensing sub-circuit 210 includes a compensation resistor R1 and a current source circuit 15. In one embodiment, the compensation resistor R1 is coupled between the drain voltage VD1 of the first switch Q1 and the first error amplifier circuit 11. The current source circuit 15 is coupled to the compensation resistor R1 to generate an offset voltage VR1 across the compensation resistor R1. In one specific embodiment, the drain-source voltage of the third switch Q3 is controlled, via the feedback control of the first error amplifier circuit 11, to be approximately equal to the sum of the drain-source voltage of the first switch Q1 and the offset voltage VR1. Accordingly, a maximum absolute value of the first switch negative current is positively correlated with the offset voltage VR1. More specifically, the product of the absolute value of the first switch negative current multiplied by the conductive resistance of the first switch Q1 is less than or equal to the offset voltage VR1.

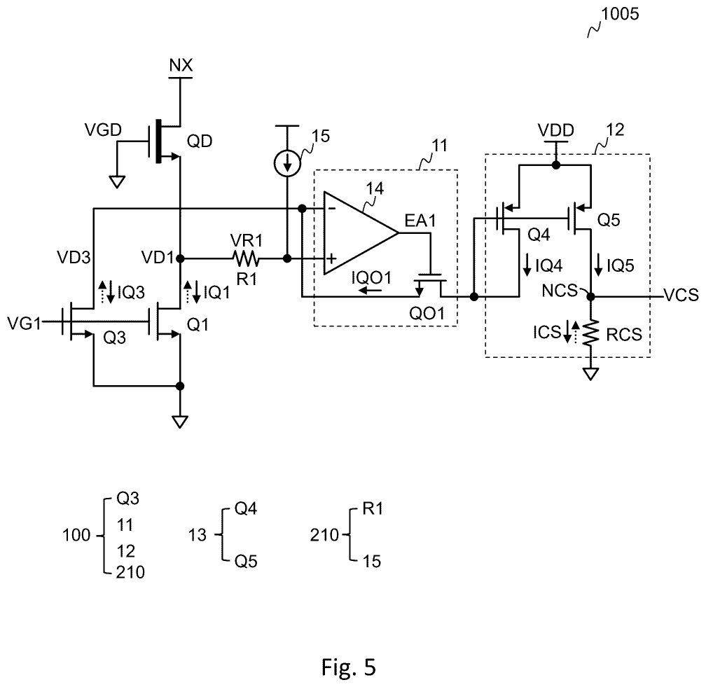

FIG. 6 illustrates a schematic diagram of an embodiment of the switch circuit with current sensing functionality according to the present invention. The switch circuit 1006 shown in FIG. 6 corresponds to a specific embodiment of the switch circuit 1003B in FIG. 3B. In one embodiment, the negative current sensing sub-circuit 220 includes a second error amplifier circuit 21 and a current-to-voltage conversion circuit 22. In this embodiment, the current-to-voltage conversion circuit 22 includes a second current mirror circuit 23. In one embodiment, the second error amplifier circuit 21 is configured to control the drain voltage VD3 of the third switch Q3 to track the drain voltage VD1 of the first switch Q1 through feedback control, such that the third switch negative current is positively correlated with the first switch negative current. In one embodiment, the second current mirror circuit 23 is coupled between an output terminal of the second error amplifier circuit 21 and the sensing node NCS, and is configured to generate a negative sensing current based on the third switch negative current.

It should be noted that, in the embodiments of FIGS. 5 and 6, the sensing current ICS includes a positive sensing current (as shown by the solid lines) and a negative sensing current (as shown by the dashed lines), wherein the positive sensing current flows in one direction and the negative sensing current flows in the opposite direction. From another perspective, the positive sensing current is greater than or equal to 0, and the negative sensing current is less than or equal to 0.

Referring still to FIG. 6, in one embodiment, the second error amplifier circuit 21 includes an error amplifier 24 and an output transistor QO2. In one embodiment, the error amplifier 24 is configured to generate an error amplified signal EA2 based on a voltage difference between the drain voltage VD1 of the first switch Q1 and the drain voltage VD3 of the third switch Q3. In one embodiment, the output transistor QO2 is configured as an NMOS transistor and is coupled between the drain of the third switch Q3 and the current-to-voltage conversion circuit 22, and is configured to generate an output current IQO2 based on the error amplified signal EA2, thereby controlling the drain voltage VD3 of the third switch Q3 to track the drain voltage VD1 of the first switch Q1. In one embodiment, the second current mirror circuit 23 includes transistors Q6 and Q7, and is configured to mirror a transistor current IQ6 (equal to IQO2 and −IQ3) flowing through transistor Q6 to generate a transistor current IQ7 flowing through transistor Q7 based on a negative supply voltage VSS, thereby generating a negative sensing current flowing through the sensing resistor RCS. Circuit details not described in FIG. 6 may be deduced by a person skilled in the art based on the description of FIG. 4.

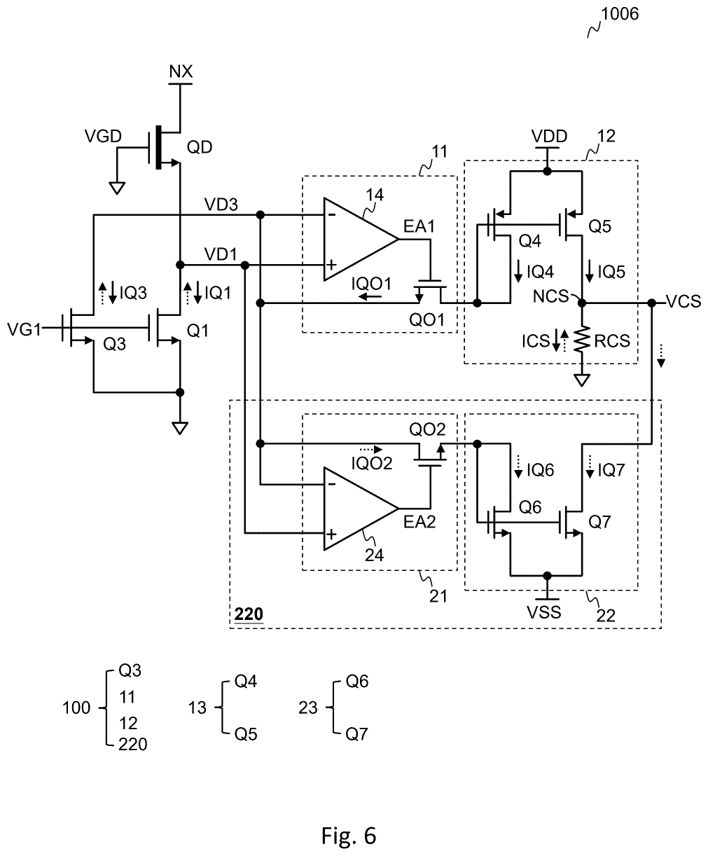

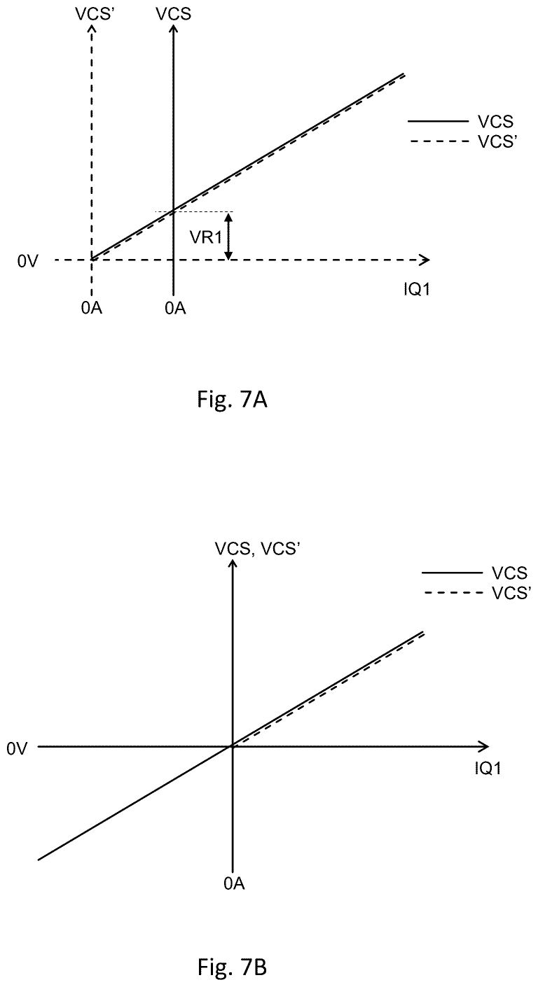

FIG. 7A illustrates a characteristic curve diagram of the sensing voltage and the first switch current corresponding to FIGS. 4 and 5 according to the present invention. The dashed line in FIG. 7A corresponds to the embodiment of FIG. 4, where the switch circuit 1002 is configured to sense the first switch positive current flowing through the first switch Q1. Therefore, as shown by the dashed line in FIG. 7A, the sensing voltage VCS′ is greater than or equal to 0, and can only represent the current range where the first switch current IQ1 is greater than 0. The solid line in FIG. 7A corresponds to the embodiment of FIG. 5, where in a preferred embodiment of FIG. 5, the switch circuit 1005 is configured to sense both the first switch positive current and the first switch negative current flowing through the first switch Q1. Accordingly, as shown by the solid line in FIG. 7A, compared with the y-axis of the sensing voltage VCS′ (dashed line), the y-axis of the sensing voltage VCS (solid line) is offset by a distance corresponding to the offset voltage VR1, which equals the product of the current provided by the current source circuit 15 and the resistance of the compensation resistor R1. In this way, as shown by the solid line in FIG. 7A, the sensing voltage VCS can represent the current range in which the first switch current IQ1 is greater than or less than 0. Since in this embodiment the actual minimum value of the sensing voltage VCS is still 0V, the maximum absolute value of the negative drain-source voltage of the first switch Q1 corresponds to the offset voltage VR1.

FIG. 7B illustrates a characteristic curve diagram of the sensing voltage and the first switch current corresponding to FIGS. 4 and 6 according to the present invention. The dashed line in FIG. 7B corresponds to the embodiment of FIG. 4; for details, please refer to the description of FIG. 7A. The solid line in FIG. 7B corresponds to the embodiment of FIG. 6, where in a preferred embodiment of FIG. 6, the switch circuit 1006 is configured to sense both the first switch positive current and the first switch negative current flowing through the first switch Q1. Therefore, as shown by the solid line in FIG. 7B, the sensing voltage VCS may, example, represent either a positive or negative value corresponding to a positive or negative current of the first switch current IQ1. In one embodiment, the sensing voltage VCS is capable of representing a substantially symmetric range of positive and negative currents.

It should be noted that in the characteristic curves of FIGS. 7A and 7B, the solid and dashed lines theoretically represent the same continuous curve extending across the zero crossing point. The lines are illustrated separately-rather than overlapping-for ease of recognition and illustration.

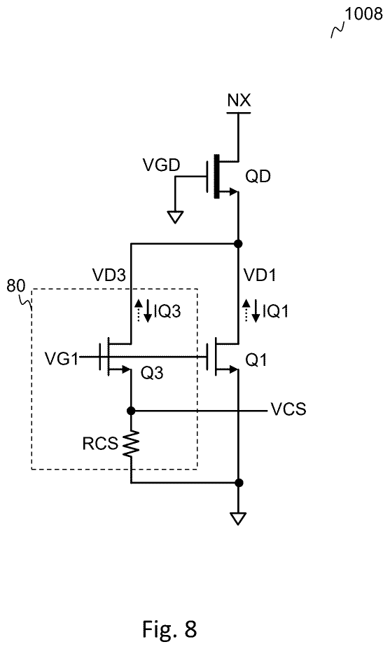

FIG. 8 illustrates a schematic diagram of an embodiment of the switch circuit with current sensing functionality according to the present invention. In one embodiment, the switch circuit 1008 includes a first switch Q1, a second switch QD, and a current sensing circuit 80. The current sensing circuit 80 includes a third switch Q3 and a sensing resistor RCS. The characteristics, coupling methods, and operational details of the first switch Q1 and the second switch QD can be deduced from the description of FIGS. 2 and 4. In one embodiment, the current sensing circuit 80 is configured to sense a first switch current IQ1 flowing through the first switch Q1. In one embodiment, the gate and source of the third switch Q3 are coupled in parallel with the gate and source of the first switch Q1, respectively. Specifically, the gate of the third switch Q3 is coupled to the gate of the first switch Q1, and the source of the third switch Q3 is coupled, in series through the sensing resistor RCS, to the source of the first switch Q1, to generate a third switch current IQ3. The sensing resistor RCS is configured to generate a sensing voltage VCS based on the third switch current IQ3, thereby sensing either a first switch positive current or a first switch negative current flowing through the first switch Q1.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A switch circuit, comprising:
a first switch and a second switch, coupled between a first terminal and a second terminal of the switch circuit, and configured to control a conductive state between the first terminal and the second terminal according to a control signal; and
a current sensing circuit, configured to sense a first switch current flowing through the first switch;
wherein the current sensing circuit includes:
a third switch, configured such that a gate and a source of the third switch are coupled in parallel with the first switch, to generate a third switch current;
a first error amplifier circuit, configured to control a drain voltage of the third switch to track a drain voltage of the first switch through feedback control, such that the third switch current is positively correlated with the first switch current; and
a current-to-voltage conversion circuit, configured to generate a sensing voltage based on the third switch current, wherein the sensing voltage is positively correlated with the first switch current.

2. The switch circuit of claim 1, wherein the current sensing circuit further includes a negative current sensing sub-circuit, configured to sense a first switch negative current flowing through the first switch; wherein the first switch current includes a first switch positive current and the first switch negative current, wherein the first switch positive current is greater than or equal to 0, and the first switch negative current is less than or equal to 0.

3. The switch circuit of claim 2, wherein the current-to-voltage conversion circuit includes:
a first current mirror circuit, coupled between an output terminal of the first error amplifier circuit and a sensing node, configured to generate a sensing current based on the third switch current; and
a sensing resistor, coupled to the sensing node, configured to generate the sensing voltage based on the sensing current.

4. The switch circuit of claim 3, wherein the third switch current includes a third switch positive current and a third switch negative current, wherein the third switch positive current is greater than or equal to 0, and the third switch negative current is less than or equal to 0;
wherein the negative current sensing sub-circuit includes:
a second error amplifier circuit, configured to control the drain voltage of the third switch to track the drain voltage of the first switch through feedback control, such that the third switch negative current is positively correlated with the first switch negative current; and
a second current mirror circuit, coupled between an output terminal of the second error amplifier circuit and the sensing node, and configured to generate a negative sensing current based on the third switch negative current;
wherein the sensing current includes a positive sensing current and the negative sensing current, wherein the positive sensing current is greater than or equal to 0, and the negative sensing current is less than or equal to 0.

5. The switch circuit of claim 3, wherein the first current mirror circuit includes a first transistor and a second transistor which are MOSFETs, wherein the first transistor and the second transistor operate in a saturation region

6. The switch circuit of claim 2, wherein the negative current sensing sub-circuit includes:
a compensation resistor, coupled between the drain voltage of the first switch and the first error amplifier circuit; and
a current source circuit, coupled to the compensation resistor to generate an offset voltage across the compensation resistor.

7. The switch circuit of claim 6, wherein a maximum absolute value of the first switch negative current is positively correlated with the offset voltage.

8. The switch circuit of claim 2, wherein the first switch and the third switch are MOSFETs and simultaneously operate in a linear region or a saturation region.

9. The switch circuit of claim 2, wherein the first error amplifier circuit includes:
an error amplifier, configured to generate an error amplified signal based on a voltage difference between the drain voltage of the first switch and the drain voltage of the third switch; and
an output transistor, coupled between a drain of the third switch and the current-to-voltage conversion circuit, configured to control the drain voltage of the third switch to track the drain voltage of the first switch based on the error amplified signal.

10. The switch circuit of claim 2, wherein the second switch is configured as a depletion-mode Metal-Oxide-Semiconductor Field-Effect Transistor (MOSFET), and the first switch and the third switch are configured as enhancement-mode MOSFETs.

11. A switch circuit, comprising:
a first switch and a second switch, coupled between a first terminal and a second terminal of the switch circuit, and configured to control a conductive state between the first terminal and the second terminal according to a control signal; and
a current sensing circuit, configured to sense a first switch current flowing through the first switch;
wherein the current sensing circuit includes:
a sensing resistor; and
a third switch, wherein a gate of the third switch is configured to be coupled to a gate of the first switch, and a source of the third switch is configured to be coupled, in series through the sensing resistor, to a source of the first switch, to generate a third switch current;
wherein the sensing resistor generates a sensing voltage based on the third switch current, wherein the sensing voltage is proportional to the first switch current.

12. The switch circuit of claim 11, wherein the first switch current includes a first switch positive current and a first switch negative current, wherein the first switch positive current is greater than or equal to 0, and the first switch negative current is less than or equal to 0.
